(19) United States
(12) Patent Application Publication
(10) Pub. No.: US 2016/0286534 A1
(43) Pub. Date: Sep. 29, 2016

(54) EARLY DETERMINATION IN HIGH-SPEED SHARED CONTROL CHANNEL DECODING

(71) Applicant: QUALCOMM Incorporated, San Diego, CA (US)

(72) Inventors: Chulong Chen, San Jose, CA (US); Nate Chizgi, Sunnyvale, CA (US); Harish Venkatachari, Sunnyvale, CA (US)

(21) Appl. No.: 14/841,027

(22) Filed: Aug. 31, 2015

Related U.S. Application Data
(60) Provisional application No. 62/137,055, filed on Mar. 23, 2015.

(51) Int. Cl. H04W 72/04; H03M 13/00; H04L 1/00

(52) U.S. Cl. CPC H04W 72/042; H04L 1/0067; H04L 1/0054; H03M 13/653

(57) ABSTRACT

The disclosure provides for determining whether an encoded multi-part message in a channel is intended for a user equipment (UE). The UE may receive a codeword that can be a component of the encoded multi-part message. The UE may also de-mask the received codeword based on an assigned identifier assigned to the UE to provide a data sequence. The UE may also damask the received codeword based on re-encoding the data sequence to provide a detected identifier. The UE can also compare the detected identifier to the assigned identifier. The UE can be determined to be the intended recipient of the encoded multi-part message when the detected identifier is equal to the assigned identifier. The disclosure also provides for jointly determining a mask and a data sequence that approximates the encoded multi-part message.

### CROSS-REFERENCE TO RELATED APPLICATION(S)

This application claims priority to U.S. Provisional Application Ser. No. 62/137,055, entitled, “IMPROVED EARLY DETERMINATION IN HIGH-SPEED SHARED CONTROL CHANNEL DECODING,” and filed on Mar. 23, 2015, which is assigned to the assignee hereof and hereby expressly incorporated by reference herein in its entirety.

### BACKGROUND

Aspects of the present disclosure relate generally to wireless communication systems, and more particularly, to control channel signaling.

Wireless communication networks are widely deployed to provide various communication services such as telephony, video, data, messaging, broadcasts, and so on. Such networks, which are usually multiple access networks, support communications for multiple users by sharing the available network resources. One example of such a network is the UMTS Terrestrial Radio Access Network (UTRAN). The UTRAN is the radio access network (RAN) defined as a part of the Universal Mobile Telecommunications System (UMTS), a third generation (3G) mobile phone technology supported by the 3rd Generation Partnership Project (3GPP). The UMTS, which is the successor to Global System for Mobile Communications (GSM) technologies, currently supports various air interface standards, such as Wideband-Code Division Multiple Access (W-CDMA), Time Division-Code Division Multiple Access (TD-CDMA), and Time Division-Synchronous Code Division Multiple Access (TD-SCDMA). The UMTS also supports enhanced 3G data communications protocols, such as High Speed Packet Access (HSPA), which provides higher data transfer speeds and capacity to associated UMTS networks.

In sending communications in some wireless communication network, for example in sending control signaling over a high speed shared control channel (HS-SCCH) in a UMTS system, a transmitter (e.g., a base station) can scramble (e.g., mask) a message using a user-specific sequence to create a codeword, which can ensure that only the intended party can decode it. In the reception of such a codeword, the receiver (e.g., a user equipment) first descrambles (e.g., de-masks) the received codeword with a previously-assigned masking sequence before performing decoding. If cyclic redundancy check (CRC) bits are attached, they can be used to determine the correctness of the masking sequence used in the decoding.

When a receiver needs to make a decision before the CRC bits are even received, such as may occur in a multi-part message when the receiver is trying to determine whether or not it is the intended recipient, a conventional method calculates a correlation between the received message and a re-encoded message and compares the correlation with certain thresholds that identify a match. However, it is known that detection accuracy of the receiver degrades greatly in an imperfect channel. As the decision is often used to abort the transmission or reception of the multi-part message, the conventional method can result in serious degradation in the throughput of the wireless communication network under noisy channel conditions.

Thus, improvements in processing of messages are desired.

### SUMMARY

The following presents a simplified summary of one or more aspects in order to provide a basic understanding of such aspects. This summary is not an extensive overview of all contemplated aspects, and is intended to neither identify key or critical elements of all aspects nor delineate the scope of any or all aspects. Its sole purpose is to present some concepts of one or more aspects in a simplified form as a prelude to the more detailed description that is presented later.

In an aspect, for example, the disclosure provides for a method of determining whether an encoded multi-part message in a channel is intended for a user equipment (UE). The method includes receiving a codeword. The codeword can be a component of the encoded multi-part message. The method also includes demasking the received codeword based on an assigned identifier assigned to the UE to produce a data sequence. The method may also include demasking the received codeword based on re-encoding the data sequence to provide a detected identifier. The method may also include comparing the detected identifier to the assigned identifier. In an aspect, the UE can be determined to be the intended recipient of the encoded multi-part message when the detected identifier is equal to the assigned identifier.

In an aspect, the disclosure provides for an apparatus for determining whether an encoded multi-part message in a channel is intended for a UE. The apparatus includes means for receiving a codeword. The codeword is a component of the encoded multi-part message. The apparatus also includes means for demasking the received codeword based on an assigned identifier assigned to the UE to produce a data sequence. The apparatus also includes means for demasking the received codeword based on re-encoding the data sequence to provide a detected identifier. The apparatus also includes means for comparing the detected identifier to the assigned identifier. In an aspect, the UE is determined to be the intended recipient of the encoded multi-part message when the detected identifier is equal to the assigned identifier.

In an aspect, the disclosure provides for a computer-readable medium storing computer-executable code for determining whether an encoded multi-part message in a channel is intended for a UE. The medium includes code for receiving a codeword. The codeword is a component of the encoded multi-part message. The medium also includes code for demasking the received codeword based on an assigned identifier assigned to the UE to produce a data sequence. The medium also includes code for demasking the received codeword based on re-encoding the data sequence to provide a detected identifier. The medium also includes code for comparing the detected identifier to the assigned identifier. In an aspect, the UE is determined to be the intended recipient of the encoded multi-part message when the detected identifier is equal to the assigned identifier.

In an aspect, the disclosure provides for an apparatus for determining whether an encoded multi-part message in a channel is intended for a UE. The apparatus includes at least one processor. The apparatus also includes a memory coupled to the at least one processor. The apparatus also includes a transceiver configured to receive at least the encoded multi-part message. The apparatus also includes a bus coupled to the at least one processor, transceiver, and memory. In an aspect, the at least one processor is configured to receive a codeword. The codeword is a component of the encoded multi-part message. The at least one processor is also configured to demask the received codeword based on an assigned identifier assigned to the UE to produce a data sequence. The at least one processor is also configured to demask the received codeword based on re-encoding the data sequence to provide a detected identifier. The at least one processor is also configured to compare the detected identifier to the assigned identifier. In an aspect, the UE is determined to be the intended recipient of the encoded multi-part message when the detected identifier is equal to the assigned identifier.

The disclosure also provides for a method of decoding an encoded multi-part message in a channel. The method includes choosing an initial value for an iterative identifier. The method also includes iterating , until the value of the iterative identifier converges to within a predetermined threshold. The iteration can include deriving a mask from the iterative identifier and demasking a received codeword based on the derived mask. The codeword may be a component of the encoded multi-part message. The codeword may provide an iterative data sequence. The iteration can also include demasking the received codeword based on the iterative data sequence to provide an updated value for the iterative identifier. The iterative data sequence can be re-encoded. The method can also include re-masking the iterative data sequence using the derived mask based on the iterative identifier and the re-encoded iterative data sequence at a point of convergence. The method can also include computing a correlation value between the re-masked iterative data sequence and the received codeword.

In another aspect, the disclosure provides an apparatus for decoding an encoded multi-part message in a channel. The apparatus includes means for choosing an initial value for an iterative identifier. The apparatus also includes means for iterating, until the value of the iterative identifier converges to within a predetermined threshold. The means for iterating can include means for deriving a mask from the iterative identifier and means for demasking a received codeword based on the derived mask. The received codeword may be a component of the enclosed multi-part message. The codeword may provide an iterative data sequence. The means for iterating can also include means for demasking the received codeword based on the iterative data sequence to provide an updated value for the iterative identifier. The iterative data sequence can be re-encoded. The apparatus can also include means for re-masking the iterative data sequence using the derived mask based on the iterative identifier and the re-masked iterative data sequence at a point of convergence. The apparatus can also include means for computing a correlation value between the re-encoded iterative data sequence and the received codeword.

In an aspect, the disclosure provides for a computer-readable medium storing computer-executable code for decoding an encoded multi-part message in a channel. The medium includes code for choosing an initial value for an iterative identifier. The medium also includes code for iterating, until the value of the iterative identifier converges to within a predetermined threshold. The code for iterating can include code for deriving a mask from the iterative identifier and demasking a received codeword based on the derived mask. The received codeword may be a component of the enclosed multi-part message. The codeword may provide an iterative data sequence. The code for iterating can also include code for demasking the received codeword based on the iterative data sequence to provide an updated value for the iterative identifier. The iterative data sequence can be re-encoded. The medium can also include code for re-masking the iterative data sequence using the derived mask based on the iterative identifier and the re-encoded iterative data sequence at a point of convergence. The medium can also include code for computing a correlation value between the re-masked iterative data sequence and the received codeword.

In an aspect, the disclosure provides for an apparatus for decoding an encoded multi-part message in a channel. The apparatus includes at least one processor. The apparatus also includes a memory coupled to the at least one processor. The apparatus also includes a transceiver configured to receive at least the encoded multi-part message. The apparatus also includes a bus coupled to the at least one processor, transceiver, and memory. In an aspect, the at least one processor is configured to choose an initial value for an iterative identifier. The at least one processor is also configured to iterating, until the value of the iterative identifier converges to within a predetermined threshold. For the iteration, the at least one processor is configured to derive a mask from the iterative identifier, demask a received codeword based on the derived mask to provide an iterative data sequence, and demask the received codeword bbased on the iterative data sequence to provide an updated value for the iterative identifier, which is re-encoded. The received codeword may be a component of the encoded multi-part message. The at least one processor is also configured to re-mask the iterative data sequence using the derived mask based on the iterative identifier and the re-encoded iterative data sequence at the point of convergence. The at least one processor is also configured to compute a correlation value between the re-masked iterative data sequence and the received codeword.

These and other aspects of the invention will become more fully understood upon a review of the detailed description, which follows.

### BRIEF DESCRIPTION OF THE DRAWINGS

FIG. 1 is a block diagram illustrating an example communications network including a base station in communication with a user equipment having a channel messaging component operable to determine correctness of an assigned masking sequence in decoding a received encoded message or to blindly determine a masking sequence for use in decoding an encoded message.

FIG. 2 is a block diagram illustrating an example of coding and decoding components and operations associated with the base station and user equipment of FIG. 1 in accordance with one or more of the disclosed aspects.

FIG. 3 is a flowchart illustrating an example method of wireless communications to determine correctness of an assigned masking sequence in decoding a received encoded message, which may be performed by the user equipment of FIG. 1, in accordance with one or more of the disclosed aspects.

FIG. 4 is a flowchart illustrating an example method of wireless communications to blindly determine a masking sequence and encoded message, which may be performed by the user equipment of FIG. 1, in accordance with one or more of the disclosed aspects.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures are shown in block diagram form in order to avoid obscuring such concepts. In an aspect, the term “component” as used herein may be one of the parts that make up a system, may be hardware, firmware, and/or software, and may be divided into other components.

The disclosure provides a communications device, such as a user equipment (UE), configured to determine whether an encoded multi-part message received in a shared channel is intended for the UE before all parts of the multi-part message are received. In particular, the communications device operating according to one aspect of the present disclosure may utilize a known, assigned UE identifier and a UE-specific coding structure of a masking sequence used in encoding a received first part of the multi-message in order to determine, based on receipt of the first part of the multi-message, whether the multi-part message is intended for the UE.

For example, in an aspect, the present disclosure provides for demasking and decoding of a first part of an encoded multi-part message in a shared channel before all parts of the multi-part message are received. In particular, the present disclosure provides for determining the contents of a received first part of the encoded multi-part message by applying a mask (e.g., a sequence of bits that acts as a key and may be specific to a UE) to decode the encoded multi-part message, where the mask is based on an assigned identifier of the communications device.

For instance, in a UMTS system, the shared channel may be the high speed shared control channel (HS-SCCH), and the encoded multi-part message may be the transmitted HS-SCCH subframe. The HS-SCCH subframe may be split into two parts, referred to as Part 1 (which contains UE identity (Xᵤₑ), channelization code (X_{cc}) and modulation scheme information (Xₘₛ)) and Part 2 (which contains Xᵤₑ, transport block size (X_{tbs}), hybrid-ARQ-related parameters (Xₕₐₚ), redundancy and constellation version (Xᵣᵥ), and a new data indicator (X_{nd})). As such, the received first part, which may also be referred to as a codeword, may be, for example, Part 1 of the HS-SCCH subframe. Also, a UE-specific cyclic redundancy check (CRC) may be calculated over all of Part 1 and Part 2, and included in Part 2, where the CRC is typically used to identify whether the transmitted encoded multi-part message is intended for the UE. Further, for example, the mask may be a sequence of bits based on an Xᵤₑ, which may be the H-RNTI (that may be specifically assigned to the UE), and the present aspects utilize the relationship between the H-RNTI, the mask, and the codeword to determine if the received first part, and hence the encoded multi-part message, is intended specifically for the UE before all parts of the encoded multi-part message, and in particular the CRC bits, are received and/or decoded.

For instance, a user equipment (UE) can receive, from the network through a shared physical channel, a codeword that is one part of a multi-part message. The UE can demask and decode this initial codeword, e.g., before all of the multi-part message is received, using a UE-specific descrambling mask to produce an encoded data sequence for further decoding. In order to correctly demask and decode the information carried by the codeword, the UE has to use the same mask that was used to initially mask the information bit sequence. In the present aspects, the UE can determine, based on the correct or incorrect demasking and decoding of the initial codeword using the assigned mask, whether the multi-part message is intended specifically for the UE. When the UE is not the intended recipient, the UE can stop reception and/or decoding of the remaining parts of the multi-part message.

In another aspect, the present disclosure also provides for blindly decoding an encoded multi-part message, e.g., without a known assigned identifier (e.g., H-RNTI) associated with a mask used to demask the received codeword. In this case, the present disclosure provides for jointly determining the mask and the contents of the received multi-part message when the receiving device does not initially know the mask used for the message. This determination may be based on a process that iteratively uses potentially-valid identifiers to generate masks and demask the received codeword. The UE can compare the results of the demasking process using different masks to identify the most-likely identifier that was used to generate the mask that masked the encoded information bit sequence to produce the encoded multi-part message. Once a most-likely mask is detected, the remaining parts of the multi-part message and subsequent encoded messages can be demasked using the detected mask.

For example, in this case, a UE can receive, from the network through a channel, a codeword that is a component of a multi-part message (e.g., Part 1 of a HS-SCCH subframe). To begin the descrambling process, the UE can choose an initial value for an identifier (e.g., an H-RNTI), and the chosen initial identifier value may be used to derive a mask. The UE can then use the initially-derived mask to demask the codeword (and then decode the encoded data sequence) to produce an initial data sequence. The UE can then re-encode the initial data sequence and use the re-encoded data sequence to demask (and then decode) the codeword to produce a new mask. The UE can derive from this new mask a new identifier. In an aspect, the UE can iteratively repeat the process by demasking the codeword using the new mask, thereby producing new sets of masks and data sequences repeatedly.

For example, in one aspect, the UE can iteratively perform a demasking and decoding loop, using new values for the mask and data sequence until the value of the mask converges or until a preset maximal number of iterations is reached. Once the iterative loop stops, the UE can determine a correlation value between the received codeword and a codeword generated using the derived mask and the data sequence. The UE may then use the chosen mask to demask and decode the remaining parts of the encoded, multi-part message. In another aspect, the UE can perform the iterative loop for multiple initial identifiers or a predetermined amount of time. In such instances, the UE may produce multiple masks that reach convergence (which may occur, for example, when the initial identifiers to produce the masks are chosen at random). When this occurs, the UE can choose to use the derived mask that produces a generated codeword with the highest associated correlation value relative to the received codeword. The UE may then use the chosen mask to demask and decode the remaining parts of the encoded, multi-part message.

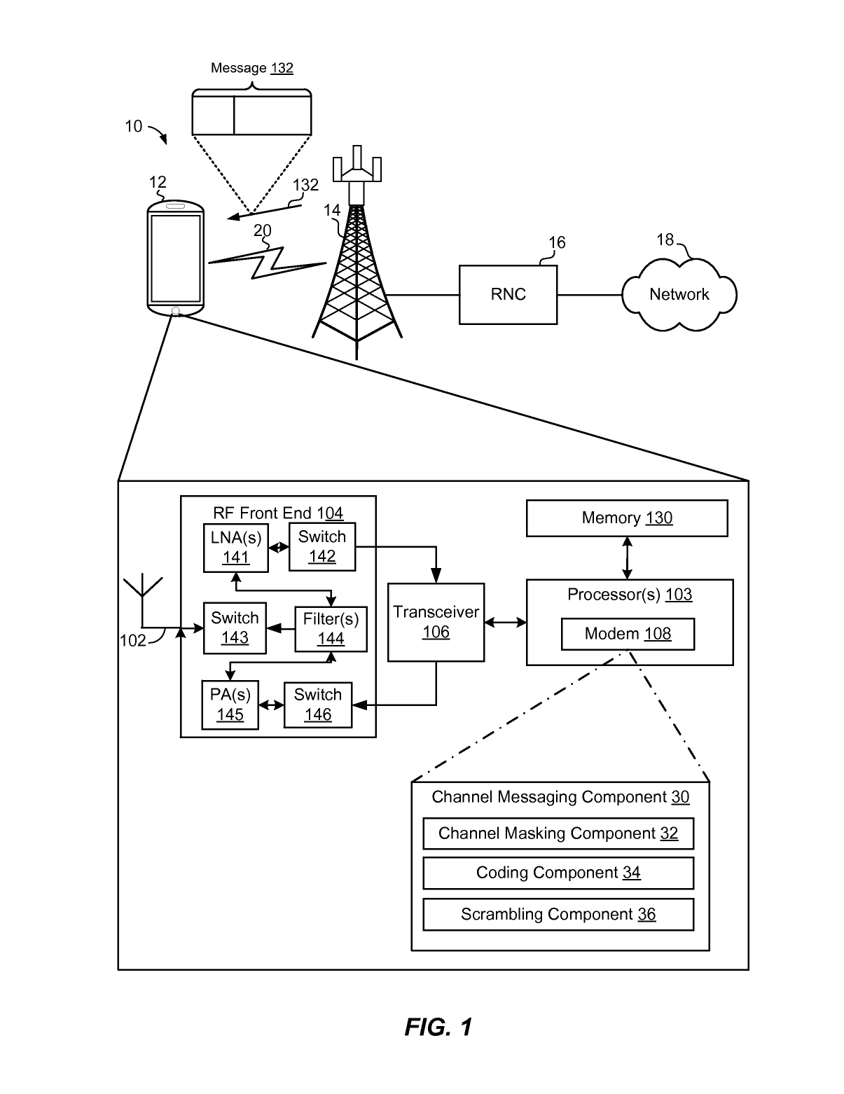

Referring to FIG. 1, in an aspect, a wireless communication system 10 includes at least one UE 12 in communication coverage of at least one network entity 14 (e.g., base station or node B). For example, UE 12 can communicate with a network 18 via network entity 14 and a radio network control (RNC) 16. In an aspect, UE 12 may include one or more processors 103 and at least one memory 130 that may operate in combination with channel messaging component 30 to exploit a code structure of a masking sequence used to code a multi-part message 132 to make an early determination, e.g., before all parts (including CRC bits) of the multi-part message 132 are received, as to whether or not to continue receiving and/or decoding additional portions of the multi-part message 132. In other words, channel messaging component 30 may operate to determine a correctness of a used masking sequence in decoding a received encoded message. In another aspect, channel messaging component 30 may operate to blindly decode a received encoded message by deriving a mask to decode the received encoded message.

In an aspect, the network entity 14 may be a base station such a NodeB in an UMTS network. UE 12 may communicate with a network 18 via network entity 14 and a radio network controller (RNC) 16. In some aspects, multiple UEs including UE 12 may be in communication coverage with one or more network entities, including network entity 14. In an example, UE 12 may transmit and/or receive wireless communications 20 to and/or from network entity 14.

In an aspect, network entity 14 can be configured to produce an encoded, multi-part message 132. For instance, in a UMTS system, the network entity 14 may generate and transmit a high speed shared control channel (HS-SCCH) subframe that may be one example of multi-part message 132. The HS-SCCH subframe may be split into two parts, referred to as Part 1 (which contains UE identity (Xᵤₑ), channelization code (X_{cc}) and modulation scheme information (Xₘₛ)) and Part 2 (which contains Xᵤₑ, transport block size (X_{tbs}), hybrid-ARQ-related parameters (Xₕₐₚ), redundancy and constellation version (Xᵣᵥ), and a new data indicator (X_{nd})). As discussed in 3GPP TS 25.101 (herein incorporated by reference), Part 1 may be the length of one slot, while Part 2 may be the length of two slots. In an aspect, network entity 14 may also produce a high speed downlink shared channel (HS-DSCH) subframe that includes data encoded based on information included in the HS-SCCH subframe. In an aspect, the HS-SCCH subframe and HS-DSCH subframe are components of a common, encoded multi-part message 132. In an aspect, UE 12 may decode information from the HS-SCCH subframe to first determine if it is the intended recipient before decoding remaining parts of the HS-SCCH subframe and/or the corresponding HS-DSCH subframe.

The wireless communications 20 between the UE 12 and the network entity 14 may include signals transmitted by either the network entity 14 or the UE 12. The wireless communications 20 can include downlink channels transmitted by the network entity 14. For example, the network entity 14 may transmit high speed shared control channel (HS-SCCH), high-speed downlink shared channel (HS-DSCH), high-speed physical downlink shared channel (HS-PDSCH), downlink dedicated physical control channel (DL-DPCCH), or a fractional dedicated physical channel (F-DPCH).

In some aspects, UE 12 may also be referred to by those skilled in the art (as well as interchangeably herein) as a mobile station, a subscriber station, a mobile unit, a subscriber unit, a wireless unit, a remote unit, a mobile device, a wireless device, a wireless communications device, a remote device, a mobile subscriber station, an access terminal, a mobile terminal, a wireless terminal, a remote terminal, a handset, a terminal, a user agent, a mobile client, a client, or some other suitable terminology. A UE 12 may be a cellular phone, a personal digital assistant (PDA), a wireless modem, a wireless communication device, a handheld device, a tablet computer, a laptop computer, a cordless phone, a wireless local loop (WLL) station, a global positioning system (GPS) device, a multimedia device, a video device, a digital audio player (e.g., MP3 player), a camera, a game console, a wearable computing device (e.g., a smart-watch, smart-glasses, a health or fitness tracker, etc), an appliance, a sensor, a vehicle communication system, a medical device, a vending machine, a device for the Internet-of-Things, or any other similar functioning device. Additionally, network entity 14 may be a macrocell, picocell, femtocell, relay, Node B, mobile Node B, UE (e.g., communicating in peer-to-peer or ad-hoc mode with UE 12), or substantially any type of component that can communicate with UE 12 to provide wireless network access at the UE 12.

In an aspect, the one or more processors 103 of UE 12 can include a modem 108 that uses one or more modem processors. The various functions related to channel messaging component 30 may be included in modem 108 and/or processors 103 and, in an aspect, can be executed by a single processor, while in other aspects, different ones of the functions may be executed by a combination of two or more different processors. For example, in an aspect, the one or more processors 103 may include any one or any combination of a modem processor, or a baseband processor, or a digital signal processor, or a transmit processor, or an application specific integrated circuit (ASIC), or a transceiver processor associated with transceiver 106. In particular, the one or more processors 103 may operate with memory 130 to execute operations and/or components included in channel messaging component 30, including a channel masking component 32 for generating a mask for descrambling encoded messages, coding component 34 for encoding and decoding an input, and a scrambling component 36 for scrambling and descrambling an input codeword. In an aspect, the one or more processors 103 may be coupled to the transceiver 106 and/or memory 130 via at least one bus 105.

According to the present aspects, channel messaging component 30 may include specially configured hardware and/or software executable by processor 103 in conjunction with memory 130 for processing messages received through wireless communications 20 in order to provide an early indication, e.g., prior to decoding all of the CRC bits, whether or not subsequent parts of a multi-part message 132 need to be decoded. For example, the multi-part message 132 can be a message having different portions, such as but not limited to: an HS-SCCH subframe having a part 1 (e.g., containing UE identity, channelization code, and modulation scheme information, such as in a first slot of a HS-SCCH frame) and a part 2 (e.g., containing UE identity, transport block size, hybrid-ARQ-related parameters, redundancy and constellation version, and a new data indicator, such as in a second and third slots of the HS-SCCH frame). Channel messaging component 30 can operate on a first portion of the multi-part message 132, e.g., part 1 of the HS-SCCH subframe, based on a code structure of a masking sequence, to determine whether or not to continue to receive and/or decode a subsequent portion, e.g., part 2 of the HS-SCCH subframe and/or one or more HS-DSCH subframes, thereby saving UE resources. In an aspect, the term “component” as used herein may be one of the parts that make up a system, may be hardware, firmware, and/or software, and may be divided into other components. Channel messaging component 30 may include a channel masking component 32, a coding component 34, and a scrambling component 36.

In an aspect, channel masking component 32 may include specially configured hardware and/or software code executable by processor 103 in conjunction with memory 130 for generating a mask (e.g., “UE mask”, “UE-specific mask”, etc.) to be used by the scrambling component 36 of UE 12 to demask (e.g., descramble) received encoded multi-part messages 132. In an aspect, for example, network entity 14 may forward an encoded multi-part message 132 and may use a specific mask such that only a recipient that has the same specific mask can successfully demask the and decode the encoded multi-part message 132. For example, network entity 14 can use a UE-specific mask (e.g., a mask based on a UE-specified assigned identifier) such that only the UE that has the same mask (e.g., the intended recipient) can successfully demask and decode the sent encoded multi-part message 132.

In an aspect, channel masking component 32 can include or can receive an identifier to generate the mask. In an aspect, the identifier can be a unique identifier associated with UE 12 or assigned to UE 12. For example, UE 12 can have an associated radio network temporary identifier (RNTI); in a HS-DSCH channel, the UE 12 may have a HS-DSCH RNTI (“H-RNTI”). In an aspect, channel masking component 32 can include a convolutional coding component to convert the identifier into a new value (“bi”) and a puncturing component to resize the output from the convolutional coding component (“ci”). For example, channel masking component 32 can receive a 16-bit H-RNTI identifier as an input, use a half-rate Viterbi decoder to produce a 48-bit bi, and use an 8-bit puncturing component to output a 40-bit UE-specific mask (“UE_MASK” or “M_{A}”).

In an aspect, coding component 34 may include specially configured hardware and/or software code executable by processor 103 in conjunction with memory 130 for encoding and/or decoding an input. For example, coding component 34 can receive an encoded data sequence as an input and can decode it to produce the (decoded) data sequence. Similarly, channel messaging component 30 can use coding component 34 to encode a data sequence; this may occur, for example, when channel messaging component 30 re-encodes a data sequence. In an aspect, channel messaging component 30 can use coding component 34 to encode a UE identifier or decode a UE mask, respectively. In an aspect, coding component 34 can comprise a Viterbi encoder/decoder. Similarly, in an aspect, channel messaging component 30 can use coding component 34 to determine a data sequence based on a demasked codeword.

In an aspect, scrambling component 36 may include specially configured hardware and/or software code executable by processor 103 in conjunction with memory 130 for scrambling (e.g., masking) and descrambling (e.g., demasking) an input data sequence or codeword, respectively. Channel messaging component 30 can use scrambling component 36, for example to reverse a masking technique employed on a codeword, e.g., to perform de-scrambling. For example, scrambling component 36 can receive a codeword (e.g., the encoded multi-part message 132) and a specific UE mask as inputs. In an aspect, the encoded multi-part message 132 may be the product of an XOR operation between the specific UE mask and an information bit sequence. The output of the demasking operation of scrambling component 36 (e.g., another XOR operation) using the encoded multi-part message 132 and specific UE mask may then be an encoded data sequence that is based upon using the specific UE mask. For example, scrambling component 36 can use the received codeword and the specific UE mask to produce an encoded data sequence. For example, scrambling component 36 may perform an XOR operation on the received codeword and the specific UE mask (e.g., the 40-bit sequence derived from the assigned H-RNTI) and may generate the encoded data sequence. When decoded, the resultant data sequence may differ from other data sequences, based on the UE mask used by scrambling component 36 during the XOR operation. Use of a different UE mask may result in a different encoded data sequence; when the UE masked used in the descrambling process is the same mask used in the initial scrambling process to produce the encoded multi-part message 132, the resultant encoded data sequence, when decoded, may be the information bit sequence.

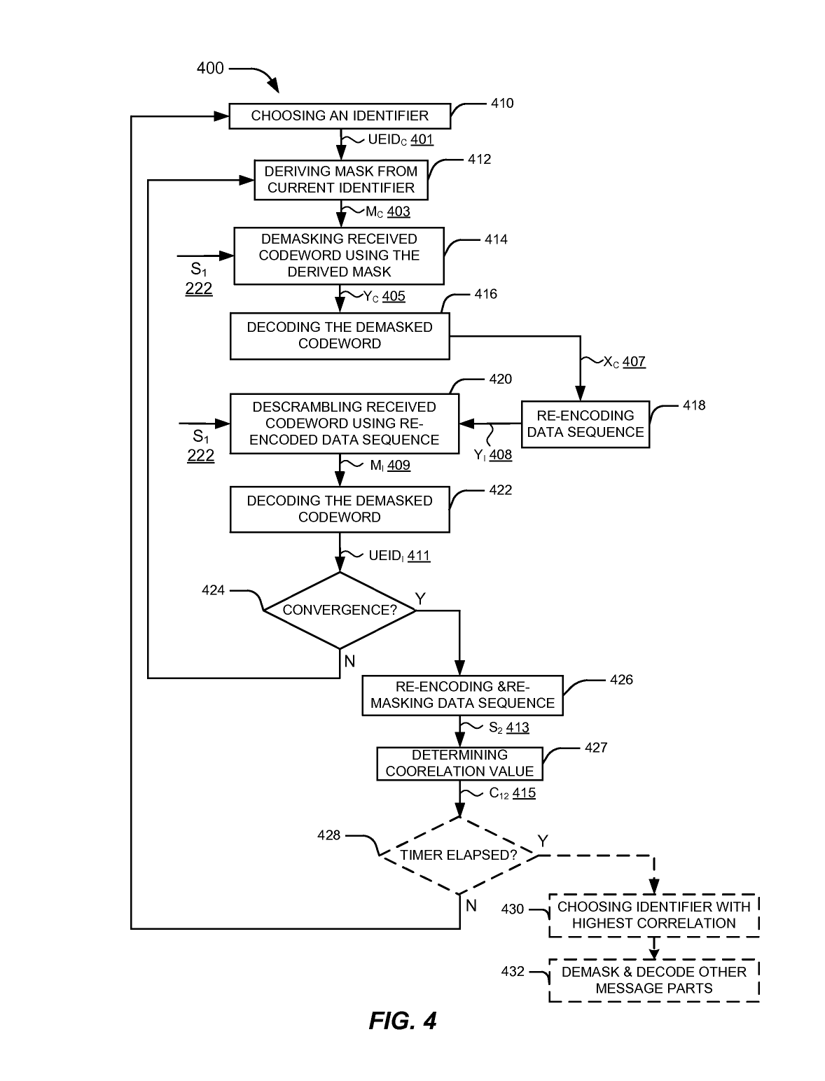

Correspondingly, scrambling component 36 may receive the codeword (e.g., the encoded multi-part message 132) and an encoded data sequence as inputs. The resultant output may be a mask; a different encoded data sequence would result in a different mask. When decoded, the mask may produce a specific identifier. In an aspect, scrambling component 36 may use an encoded data sequence and a specific UE mask as inputs and produce an codeword as an output. As will be discussed below in relation to FIG. 4, channel messaging component 30 can iteratively use scrambling component 36 with differing inputs of iteratively-updated UE masks and iteratively-updated data sequences to detect the UE mask that was used to produce the codeword received by UE 12; in such instances, UE 12 can use the detected UE mask to descramble the remaining parts of the encoded multi-part message 132.

Moreover, in an aspect, UE 12 may include RF front end 104 and transceiver 106 for receiving and transmitting radio transmissions, for example, wireless communications 20 transmitted by the network entity 14. For example, transceiver 106 may receive a packet (e.g., one or more parts of a HS-SCCH subframe and/or HS-DSCH subframe) on the HS-SCCH and/or HS-DSCH transmitted by the network entity 14. UE 12, upon receipt of a part of the message, may decode the HS-SCCH subframe part and, upon receipt of the entire HS-SCCH subframe, perform a cyclic redundancy check (CRC) to determine whether the packet was received correctly. For example, transceiver 106 may communicate with modem 108 to transmit messages generated by channel messaging component 30 and to receive messages and forward them to channel messaging component 30.

RF front end 104 may be connected to one or more antennas 102 and can include one or more low-noise amplifiers (LNAs) 141, one or more switches 142, 143, 146, one or more power amplifiers (PAs) 145, and one or more filters 144 for transmitting and receiving RF signals via wireless communications 20. In an aspect, components of RF front end 104 can connect with transceiver 106. Transceiver 106 may connect to one or more modems 108 and processor 103.

In an aspect, LNA 141 can amplify a received signal at a desired output level. In an aspect, each LNA 141 may have a specified minimum and maximum gain values. In an aspect, RF front end 104 may use one or more switches 142, 143 to select a particular LNA 141 and its specified gain value based on a desired gain value for a particular application.

Further, for example, one or more PA(s) 145 may be used by RF front end 104 to amplify a signal for an RF output at a desired output power level. In an aspect, each PA 145 may have a specified minimum and maximum gain values. In an aspect, RF front end 104 may use one or more switches 143, 146 to select a particular PA 145 and its specified gain value based on a desired gain value for a particular application.

Also, for example, one or more filters 144 can be used by RF front end 104 to filter a received signal to obtain an input RF signal. Similarly, in an aspect, for example, a respective filter 144 can be used to filter an output from a respective PA 145 to produce an output signal for transmission. In an aspect, each filter 144 can be connected to a specific LNA 141 and/or PA 145. In an aspect, RF front end 104 can use one or more switches 142, 143, 146 to select a transmit or receive path using a specified filter 144, LNA, 141, and/or PA 145, based on a configuration as specified by transceiver 106 and/or processor 103.

Transceiver 106 may be configured to transmit and receive wireless signals through antenna 102 via RF front end 104. In an aspect, transceiver may be tuned to operate at specified frequencies such that UE 12 can communicate with, for example, network entity 14. In an aspect, for example, modem 108 can configure transceiver 106 to operate at a specified frequency and power level based on the UE configuration of the UE 12 and communication protocol used by modem 108.

In an aspect, modem 108 can be a multiband-multimode modem, which can process digital data and communicate with transceiver 106 such that the digital data is sent and received using transceiver 106. In an aspect, modem 108 can be multiband and be configured to support multiple frequency bands for a specific communications protocol. In an aspect, modem 108 can be multimode and be configured to support multiple operating networks and communications protocols. In an aspect, modem 108 can control one or more components of UE 12 (e.g., RF front end 104, transceiver 106) to enable transmission and/or reception of signals from the network based on a specified modem configuration. In an aspect, the modem configuration can be based on the mode of the modem and the frequency band in use.

UE 12 may further include memory 130, such as for storing data used herein and/or local versions of applications and/or channel messaging component 30 and/or one or more of its subcomponents being executed by processor 103. Memory 130 can include any type of computer-readable medium usable by a computer or processor 103, such as random access memory (RAM), read only memory (ROM), tapes, magnetic discs, optical discs, volatile memory, non-volatile memory, and any combination thereof. In an aspect, for example, memory 130 may be a computer-readable storage medium that stores one or more computer-executable codes defining channel messaging component 30 and/or one or more of its subcomponents, and/or data associated therewith, when UE 12 is operating processor 103 to execute channel messaging component 30 and/or one or more of its subcomponents.

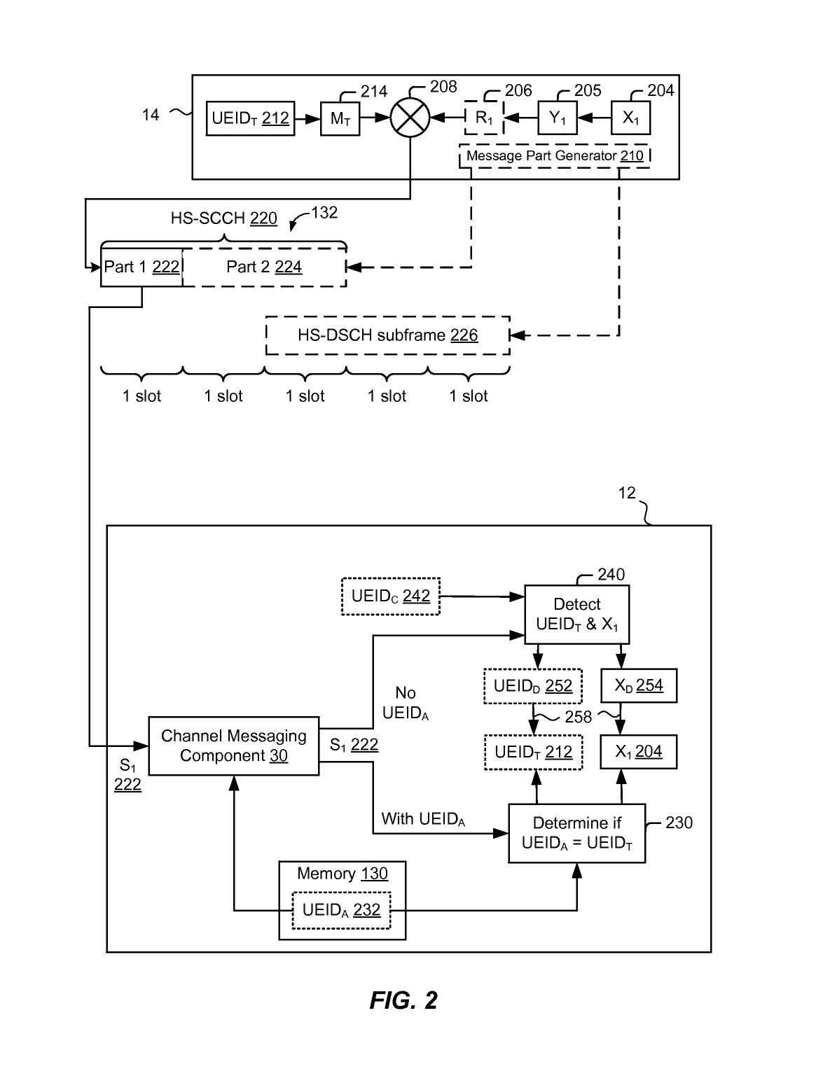

FIG. 2 is a block diagram illustrating an example of coding and decoding components and operations associated with the network entity 14 and user equipment 12 of FIG. 1 in accordance with one or more of the disclosed aspects. In an aspect, network entity 14 generates and transmits multi-part message 132 in the form of HS-SCCH subframe 220, and network entity 14 also generates a corresponding HS-DSCH subframe 226, both of which may be received and partially or fully decoded by UE 12, depending on if UE 12 is the intended recipient. More particularly, network entity 14 may generate part 1 222 of the HS-SCCH subframe 220 and transmit HS-SCCH subframe part 1 222 to UE 12. In an aspect, the transmitted HS-SCCH subframe part 1 222 of HS-SCCH subframe 220 may also be referred to as a codeword S₁ 222. Upon receipt, processor 103 and channel messaging component 30 of UE 12 may access memory 130 to determine whether it has an assigned UE identifier (UEID_{A}) 232. If so, channel messaging component 30 may use the codeword S₁ 222 and the UEID_{A} 232 to determine, at block 230, whether UE 12 was the intended recipient of the HS-SCCH subframe 220 by comparing the assigned ID 232 with the intended identifier (UEID_{T}) 212. Alternatively, if channel messaging component 30 determines that a UEID_{A} 232 is not stored, then channel messaging component 30, at block 240, can use a chosen valid UE identifier (UEID_{C}) 242 and the received codeword S₁ 222 to blindly detect a UE identifier (UEID_{D}) 252 and a data sequence (X_{D}) 254.

Referring back to the coding process at network entity 14, network entity 14 can include an information bit sequence X₁ 204 used in generation of the multi-part message 132. In an aspect, for example, information bit sequence X₁ 204 can include the channelization code (X_{cc}) and modulation scheme information (Xₘₛ) for the HS-SCCH subframe 220. Message part generator 210 or another component of network entity 14 can decode information bit sequence X₁ 204 to produce encoded information bit sequence Y₁ 205. For example, network entity can use a convolutional coding component (e.g., a Viterbi encoder) at a specified rate (e.g., ⅓) to convert X₁ 204 the encoded information bit sequence Y₁ 205. In an aspect, network entity 14 can optionally rate match the encoded information bit sequence to generate rate-matched encoded information bit sequence 206.

Network entity 14 can also use an intended or target UE identifier (UEID_{T}) 212 to mask multi-part message 132 so that only the intended recipient UE may decode it. For example, network entity 14 can use UEID_{T} 212 to specify the UE for reception of the HS-SCCH subframe 220. In an aspect, the intended recipient UE has stored an assigned UE identifier that matches the target UE identifier 212. In an aspect, message part generator 210 or another part of network entity 14 can use a coding component (e.g., a Viterbi encoder) to encode UEID_{T} 212 to produce an intended or target mask M_{T} 214. In an aspect, network entity can, at 208, mask (e.g., scramble) M_{T} 214 with Z₁ 205 (or optionally, R₁ 206) to produce codeword S₁ 222.

Further, in an aspect of the process of transmitting multi-part message 132, network entity 14 can map codeword S₁ 222 in the physical channel to a part (e.g., Part 1) of HS-SCCH subframe 222. In an aspect, codeword S₁ 222 comprises the entirety of HS-SCCH subframe part 1 222. In an aspect, message part generator 210 of network entity can also produce other values and physically map them to other subframe parts (e.g., Part 2 of HS-SCCH subframe 220). For example, message part generator 210 may add transport block size (X_{tbs}), hybrid-ARQ-related parameters (Xₕₐₚ), redundancy and constellation version (Xᵣᵥ), and a new data indicator (X_{nd}) to HS-SCCH subframe part 2 224. In an aspect, network entity may attach UEID_{T} 212 and CRC into part 2 224. In an aspect, message part generator 210 may use a coding component and/or a rate matching component to produce a codeword that comprises the entirety of HS-SCCH subframe part 2 224. In an aspect, message part generator 210 can also produce the data included in HS-DSCH subframe 226.

In an aspect, HS-SCCH subframe 220 and HS-DSCH subframe 226 each take three time slots (1 slot may equal 40 bits). UE 12 may receive HS-SCCH subframe part 1 222 in a first slot and decode the data from it in a second slot before receiving HS-DSCH subframe. As UE 12 begins to receive HS-DSCH subframe 226 before receiving the entire HS-SCCH subframe 220, waiting to use CRC to determine whether it is the intended recipient requires UE 12 to receive the entire HS-DSCH subframe 226, as UE 12 cannot decode the entire HS-SCCH subframe 220 until it has received the entire HS-DSCH subframe 226. UE 12 using the contents of HS-SCCH subframe part 1 222 to determine whether it is the intended recipient may save time and allow UE 12 to discard or ignore the HS-DSCH subframe 226 when it determines it is not the intended recipient.

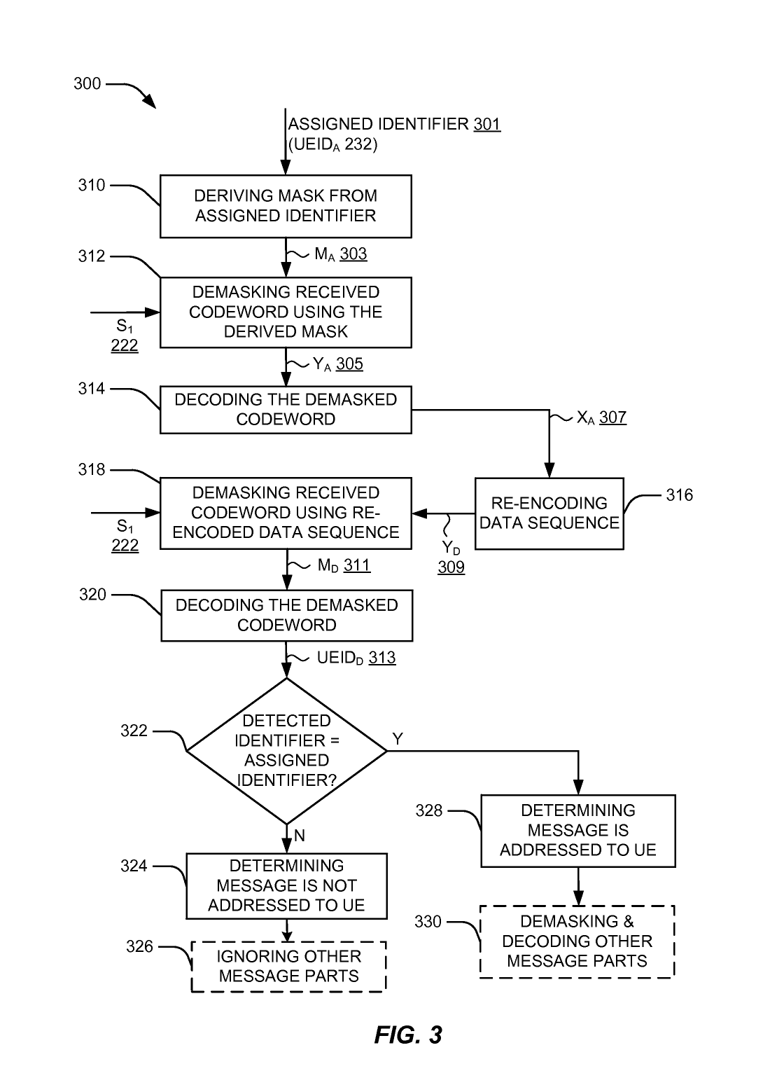

UE 12 may receive HS-SCCH subframe part 1 222 and may decode the codeword S₁ 222 included in part 1 222 based on whether it has a stored UE identifier. In an aspect, UE 12 may receive and decode S₁ 222 within the time frame of 1 slot; this may also include, after determining whether UE 12 has an assigned identifier, performing the methods included in block 230 or 240. For example, UE 12 may use channel messaging component 30 (and channel masking component 32) to determine whether a UE identifier assigned to UE 12 (e.g., UEID_{A} 232) is stored in memory 130. When channel messaging component 30 determines that memory 130 includes UEID_{A} 232, channel messaging component 30 may at block 230, determine whether the assigned identifier UEID_{A} 232 matches the target identifier UEID_{T} 212 (see, e.g., method 300 of FIG. 3). At block 230 channel messaging component 30 may use the received codeword S₁ 222 and the assigned identifier UEID_{A} 232 stored in memory 130 as inputs and may, when UE 12 is the intended recipient, produce UEID_{T} 212 and the information bit sequence X₁ 204 as outputs (alternatively, when UE 12 is not the intended recipient, channel messaging component may produce a data sequence that is not equivalent to the information bit sequence X₁ 204).

In an aspect, when channel messaging component 30 determines that memory 130 does not include UEID_{A} 232, channel messaging component at block 240 blindly detects a mask and data sequence that is similar to received codeword S₁ 222 (see, e.g., method 400 of FIG. 4). For example, channel messaging component 30 may use received codeword S₁ 222 and a chosen (optionally random) UE identifier UEID_{C} 242 as inputs to blindly detect a mask (UEID_{D} 252) and a data sequence (X_{D} 254) that largely correlates with the received codeword S₁ 222. At the highest correlation 258 (e.g., when the correlation between the codeword produced by UEID_{D} 252 and X_{D} 254 is approximately 1.0), the detected UEID is equal to the target UEID, and the detected data sequence is equivalent to the information bit sequence.

Referring to FIG. 3, in an operational aspect, a communications device such as UE 12 (FIG. 1) may perform one or more aspects of a method 300 for early determination in decoding a HS-SCCH subframe when using an assigned UE-specific identifier (such as an assigned H-RNTI). While, for purposes of simplicity of explanation, the method is shown and described as a series of acts, it is to be understood and appreciated that the method (and further methods related thereto) is/are not limited by the order of acts, as some acts may, in accordance with one or more aspects, occur in different orders and/or concurrently with other acts from that shown and described herein. For example, it is to be appreciated that a method could alternatively be represented as a series of interrelated states or events, such as in a state diagram. Moreover, not all illustrated acts may be required to implement a method in accordance with one or more features described herein.

In an aspect, at block 310, the method 300 may include deriving a UE mask from an assigned identifier. In an aspect, for example, the UE 12 can use channel masking component 32 of channel messaging component 30 to generate a derived UE mask (M_{A}) 303 based on an assigned identifier 301 assigned to UE 12 (e.g., UEID_{A} 232). In an aspect, the UE 12 can use an assigned H-RNTI as assigned identifier 301.

In an aspect, at block 312, the method 300 may include demasking a received codeword using the derived UE mask. In an aspect, for example, UE 12 may receive a portion of a message, such as an HS-SCCH subframe part 1 222, also referred to as codeword S₁ 222. Channel messaging component 30 can use scrambling component 36 to apply the UE mask M_{A} 303 derived at block 310 to demask (e.g., descramble) the received portion of the HS-SCCH subframe. This may produce an encoded data sequence (Y_{A} 305). In an aspect, block 312 may also include de-rate-matching (e.g., reversing a rate-matching procedure) of a demasked codeword R_{A} to produce encoded data sequence Y_{A} 305.

In an aspect, at block 314, the method 300 may include decoding the descrambled codeword. In an aspect, for example, channel messaging component 30 can use coding component 34 to produce a decoded data sequence (X_{A} 307) from the encoded data sequence Y_{A} 305. In an aspect, coding component 34 may process the demasked codeword using a Viterbi decoder to produce the decoded data sequence. In an aspect, the decoded data sequence may be equivalent to the information bit sequence X₁ 204 when UEID_{A} 232 is equal to the target UE identifier 212.

In an aspect, at block 316, method 300 may include re-encoding the data sequence. For example, in an aspect, UE 12 may use coding component 34 of channel messaging component 30 to re-encode data sequence X_{A} 307. In an aspect, coding component 34 may use the same convolutional coding scheme to re-encode the data sequence. For example, coding component 34 may use a ⅓ convolutional coding scheme at block 314 to decode the demasked codeword, and use the ⅓ convolutional coding scheme to re-encode the data sequence to produce re-encoded data sequence Y_{D} 309.

In an aspect, at block 318, the method 300 may include demasking the received codeword using the re-encoded sequence. In an aspect, for example, channel messaging component 30 of UE 12 can use scrambling component 36 to perform an XOR operation using the received codeword S₁ 222 and the re-encoded data sequence Y_{D} 309 as inputs to demask S₁ 222 and produce detected mask M_{D} 311. In an aspect, detected mask MD 311 may differ from assigned mask M_{A} 303.

In an aspect, at block 320, the method 300 may include decoding the demasked codeword. In an aspect, for example, channel messaging component 30 can use coding component 34 to produce a detected UE identifier (UEID_{D} 313) from the demasked codeword (e.g., the detected mask M_{D} 311 resultant of the demasking procedure of codeword S₁ 222 at block 318). In an aspect, for example, coding component 34 may use a convolutional coding scheme to produce UEID_{D} 313 from detected mask M_{D} 311. In an aspect, UE 12 could process the detected mask 311 using a Viterbi decoder to produce the detected UE identifier 313.

In an aspect, at block 322, method 300 may include comparing a detected identifier to the assigned identifier. In an aspect, for example, channel messaging component 30 can compare detected identifier (UEID_{D} 313) to the assigned identifier (UEID_{A} 232). If the channel messaging component 30 determines that the values of the identifiers match, method 300 proceeds to block 328; otherwise, method 300 proceeds to block 324.

In an aspect, at block 324, method 300 may include determining that the message is not addressed to the recipient communications device. For example, UE 12 may determine that it is not the intended recipient of the HS-SCCH subframe 220, as the HS-SCCH subframe part 1 222 was encoded using a mask (M_{T} 214) that was not the UE-specific mask used by UE 12 (M_{A} 303). This was determined in block 322 when the detected identifier UEID_{D} 313 (produced from block 320) did not match the assigned identifier UEID_{A} 232.

In an aspect, at block 326, method 300 may include ignoring other message parts. For example, in an aspect, UE 12 may ignore the other parts of the multi-part message 132, e.g., where ignoring may include ignoring such other parts already received (such that UE 12 can discard the received parts) and/or ignoring reception of remaining parts not yet received. For example, in a case where multi-part message 132 may be considered to include HS-SCCH subframe 220 and corresponding HS-DSCH subframe 226, UE 12 may determine by the end of a second time slot that it is not the intended recipient of the HS-SCCH subframe 220. At such time, UE 12 may have already received a first slot of the 2-slot HS-SCCH subframe part 2 224 while not yet receiving any of HS-DSCH subframe 226. UE 12, upon the determination at block 324, may discard the already-received parts of HS-SCCH subframe part 1 222 and part 2 224 and may ignore the remaining segments of HS-SCCH subframe part 2 224 and HS-DSCH subframe 226.

In an aspect, at block 328, method 300 may include determining that the message is addressed to the recipient communications device. For example, UE 12 may determine that it is the intended recipient of the of HS-SCCH subframe 220, as the codeword S₁ 222 or HS-SCCH subframe part 1 222 was masked using a UE-specific mask (UEID_{T} 212) that matched the assigned UE identifier (UEID_{A} 232) of UE 12. This was determined in block 322 when detected identifier UEID_{D} 313 matched the assigned identifier UEID_{A} 232, 301.

In an aspect, at block 330, method 300 may include demasking and decoding other message parts. For example, in an aspect, UE 12 may demask and subsequently decode other parts of the multi-part message 132 either already received and may demask and decode subsequently received parts. For example, UE 12 may determine by the end of a second time slot that it is the intended recipient of the HS-SCCH subframe 220; at such time, UE 12 may have already received a first slot of the 2-slot HS-SCCH subframe part 2 224 while not yet receiving any of HS-DSCH subframe 226. UE 12, upon the determination at block 328, may commence demasking and decoding the already-received portions of HS-SCCH subframe part 1 222 and part 2 224 and may subsequently demask and decode the remaining portions of HS-SCCH subframe part 2 224 and HS-DSCH subframe 226.

Method 300 therefore provides for a method of determining whether an encoded multi-part message 132 received in a shared channel is intended for the UE before all parts of the multi-part message 132 are received. UE can receive a codeword that is one part of a multi-part message 132. The UE can demask and decode this initial codeword using a UE-specific mask to produce an encoded data sequence for further decoding. In order to correctly demask and decode the information carried by the codeword, the UE has to use the same mask that was used to initially mask the information bit sequence. The UE can determine, based on the correct or incorrect demasking and decoding of the initial codeword using the assigned mask, whether the multi-part message 132 is intended specifically for the UE. When the UE is not the intended recipient, the UE can stop reception of the remaining parts of the multi-part message 132.

Referring to FIG. 4, in an operational aspect, a communications device such as UE 12 (FIG. 1) may perform one or more aspects of a method 400 for early, blind determination of an unknown mask in descrambling and decoding a HS-SCCH subframe when an assigned UE-specific identifier (such as a H-RNTI) is not known to the UE 12. In contrast to method 300 of FIG. 3, UE 12 does not determine whether it is the intended recipient of the encoded multi-part message 132; rather, UE 12 may blindly determine the mask (and detected the H-RNTI) and the contents of the encoded message based on a correlation between a codeword encoded based on a chosen identifier and the codeword received by UE 12. In an aspect, UE 12 may first determine that there is no assigned UEID_{A} 232 stored in memory 130 before performing method 400.

In an aspect, at block 410, method 400 may include choosing an initial identifier. In an aspect, for example, the channel messaging component 30 can choose an identifier (e.g., H-RNTI) where UE 12 does not know the mask used to produce the received codeword. In an aspect, the channel messaging component 30 can choose an identifier (e.g., UEID_{C} 401) at random from a set of possible values for the identifier. For example, channel messaging component 30 may choose a value (in decimal form) in the inclusive range of {0, 65535}; channel messaging component 30 may choose any value in the range with equal probability. In an aspect, channel message component 30 can use knowledge obtained earlier and/or from other sources to reduce the range of possible values for UEID_{C}.

In an aspect, at block 412, method 400 may include deriving a mask from the current identifier. Similar to block 310 of FIG. 3, in an aspect, for example, channel messaging component 30 can use channel masking component 32 to derive a mask (M_{C} 403) based on the value of the current identifier. In an aspect, the current identifier is the initially-identifier (UEID_{C} 401) selected at block 410. In another aspect, the current identifier is the iterative identifier (UEID_{I} 411) determined in block 422.

In an aspect, at block 414, the method 400 may include demasking a received codeword using the derived mask. Similar to block 312 of FIG. 3, in an aspect, for example, UE 12 may receive a codeword S₁ 222 included in HS-SCCH subframe part 1 222. Channel messaging component 30 can use scrambling component 36 to apply the mask M_{C} 403 derived at block 412 to demask the received codeword Si 222 to produce an encoded data sequence Y_{C} 405.

In an aspect, at block 416, the method 400 may include decoding the demasked codeword. Similar to block 314 of FIG. 3, in an aspect, for example, channel messaging component 30 can use coding component 34 to produce a decoded data sequence. In an aspect, for example, the coding component 34 would produce a decoded data sequence X_{C} 407 from the encoded data sequence Y_{C} 405. In an aspect, coding component 34 can process the demasked codeword using a Viterbi decoder to produce the decoded data sequence.

In an aspect, at block 418, method 400 may include re-encoding the data sequence. Similar to block 316 of FIG. 3, in an aspect, for example, channel messaging component 30 can use coding component 34 to re-encode data sequence X_{C} 407. In an aspect, coding component 34 may use a different convolutional coding scheme to re-encode the data sequence. For example, coding component 34 may use a ⅓ convolutional coding scheme at block 416 to decode the demasked codeword, while using a ½ convolutional coding scheme to re-encode the data sequence to produce re-encoded (iterative) data sequence Y₁ 408.

In an aspect, at block 420, the method 400 may include descrambling a received codeword using the re-encoded data sequence. Similar to block 318 of FIG. 3, in an aspect, for example, channel messaging component 30 of UE 12 can use scrambling component 36 to perform an XOR operation using the received codeword S₁ 222 and the re-encoded data sequence Y_{I} 408 as inputs to demask S₁ 222 and produce iterative mask M_{I} 409.

In an aspect, at block 422, the method 400 may include decoding the descrambled codeword. Similar to block 320 of FIG. 3, in an aspect, for example, channel messaging component 30 of UE 12 can use coding component 34 to produce an iterative UE identifier (UEID_{I} 411) from the demasked codeword (e.g., the iterative mask M_{I} 409 resultant of the demasking procedure of codeword S₁ 222 at block 420). In an aspect, for example, coding component 34 would use a convolutional coding scheme to produce UEID_{D} 313 from iterative mask M_{I} 409. In an aspect, UE 12 could process the iterative mask M_{I} 409 using a Viterbi decoder to produce the iterative UE identifier UEID_{I} 411.

In an aspect, at block 424, the method 400 may include determining whether the iterative identifier is converging. For example, in an aspect, channel messaging component 30 of UE 12 can determine whether the iterative UE identifier UEID_{I} 411 identifier has a value that is converging to a specific value or if the distance (e.g., Hamming distance) of successive iterative UE identifiers 411 is within a specific threshold (e.g, whether the Hamming distance is decreased from 10 to 3 to 2). For example, in an aspect, channel messaging component 30 may store one or more successive values of iterative UE identifier UEID_{I} 411. Channel messaging component 30 can compare the one or more stored values and the iterative UE identifier 411 and determine whether the values are converging to a specific value or a value range for the iterative UE identifier 411. If the channel messaging component 30 determines that there is no convergence, method 400 may return to block 412. However, if the channel messaging component 30 determines that there is convergence, method 400 can proceed to block 426.

In an aspect, at block 426, the method 400 may include re-encoding and re-masking the data sequence. In an aspect, for example, channel messaging component 30 can use coding component 34 and/or scrambling component 36 to re-encode and re-mask the data sequence Y_{I}405 produced at block 418 to produce a new codeword S₂ 413. In an aspect, channel messaging component 30 can re-mask the data sequence Y_{I} 408 using a value for the identifier determined to be at convergence; this may be the iterative UE identifier UEID_{I} 411.

In an aspect, at block 427, method 400 may include computing a correlation value between the new codeword and the received codeword. In an aspect, for example, channel messaging component 30 of UE 12 can compute a correlation value C₁₂ 415 between the new codeword S₂ 413, encoded and masked with the iterative UE identifier UEID_{I} 411,and the re-encoded data sequence Y_{I} 408, and the received codeword S₁ 222. A high correlation value may indicate that the iterative mask based on UEID_{I}411 is close to the mask based on UEID_{T} 212 used to initially mask the received codeword Si₁ 222.

In an aspect, at block 428, method 400 can optionally include determining whether a predetermined timer has elapsed. In an aspect, for example, method 400 may repeat blocks 410-428 for a specified period. Channel messaging component 30 of UE 12 may, at block 428, check to determine whether the specified period has elapsed. In an aspect, the specified period is predetermined and programmed before the reception of the encoded multi-part message 132. In another aspect, the specified period may be defined by a preset maximal number of iterations performed. Once UE 12 determines the timer has elapsed, method 400 may proceed to block 430.

In an aspect, at block 430, the method 400 may optionally include choosing the identifier with the highest correlation value. In an aspect, for example, UE 12 may save one or more UE identifiers UEID_{I}411 that were determined to reach convergence at block 424 and the corresponding correlation value C₁₂ 415 of their resultant codeword S₂ 413 (determined at block 426). Channel messaging component 30 can compare the saved correlation values C₁₂ 415 and choose the identifier UEID_{I} 411 associated with the highest correlation value C₁₂.

In an aspect, at block 432, method 400 may include demasking and decoding other message parts. Similar to block 330 of FIG. 3, in an aspect, channel messaging component 30 of UE 12 can use a mask derived from the chosen identifier UE 12 (e.g., M_{I}409) to demask and subsequently decode the entire multi-part message 132 received by the UE 12. For example, the identifier chosen at block 430 may act as an identifier matching the initial identifier UEID_{T} 212 used by network entity 14 to initially mask the information bit sequence 204. UE 12 may then demask and decode the already-received segments of HS-SCCH subframe part 1 222 and part 2 224 and may subsequently demask and decode the remaining segments of HS-SCCH subframe part 2 224 and HS-DSCH subframe 226.

Method 400 therefore provides for blindly determining the identity of a multi-part message 132 in a shared channel. In one attempt, the communications device may also decode the received codeword with a certain initial identifier, resulting in an information bit sequence. The information bit sequence may be re-encoded. The communications device may also derive an identifier from the received codeword based on the re-encoded information bit sequence. The communication device may repeat the process until convergence. The communication device may perform multiple attempts with various initial identifiers. The communication device may choose to use the result, among the results from multiple attempts, with the highest correlation metric as the final result for the decoded information sequence and determined identifier. The communications device may then used the determined identifier to decode the rest of the multi-part message 132 and other encoded messages.

Several aspects of the present disclosure have been presented with reference to a W-CDMA system. As those skilled in the art will readily appreciate, various aspects described throughout this disclosure may be extended to other telecommunication systems, network architectures and communication standards.

By way of example, various aspects may be extended to other wireless communication systems in which multi-part encoded messages are received with the encoding based on a specific identifier that may be based on an identifier specific to a UE. Examples of such other wireless communication systems may include UMTS systems and/or LTE and/or other systems. Such UMTS systems may include TD-SCDMA, High Speed Downlink Packet Access (HSDPA), High Speed Uplink Packet Access (HSUPA), High Speed Packet Access Plus (HSPA+) and TD-CDMA. Such LTE and/or other systems may include Long Term Evolution (LTE) (in FDD, TDD, or both modes), LTE-Advanced (LTE-A) (in FDD, TDD, or both modes), CDMA2000, Evolution-Data Optimized (EV-DO), Ultra Mobile Broadband (UMB), IEEE 802.11 (Wi-Fi), IEEE 802.16 (WiMAX), IEEE 802.20, Ultra-Wideband (UWB), Bluetooth, and/or other suitable systems. The actual telecommunication standard, network architecture, and/or communication standard employed will depend on the specific application and the overall design constraints imposed on the system.

In accordance with various aspects of the disclosure, an element, or any portion of an element, or any combination of elements may be implemented with a “processing system” that includes one or more processors. Examples of processors include microprocessors, microcontrollers, digital signal processors (DSPs), field programmable gate arrays (FPGAs), programmable logic devices (PLDs), state machines, gated logic, discrete hardware circuits, and other suitable hardware configured to perform the various functionality described throughout this disclosure. One or more processors in the processing system may execute software. Software shall be construed broadly to mean instructions, instruction sets, code, code segments, program code, programs, subprograms, software modules, applications, software applications, software packages, routines, subroutines, objects, executables, threads of execution, procedures, functions, etc., whether referred to as software, firmware, middleware, microcode, hardware description language, or otherwise. The software may be stored on a computer-readable medium. The computer-readable medium may be a non-transitory computer-readable medium. A non-transitory computer-readable medium includes, by way of example, a magnetic storage device (e.g., hard disk, floppy disk, magnetic strip), an optical disk (e.g., compact disk (CD), digital versatile disk (DVD)), a smart card, a flash memory device (e.g., card, stick, key drive), random access memory (RAM), read only memory (ROM), programmable ROM (PROM), erasable PROM (EPROM), electrically erasable PROM (EEPROM), a register, a removable disk, and any other suitable medium for storing software and/or instructions that may be accessed and read by a computer. The computer-readable medium may be resident in the processing system, external to the processing system, or distributed across multiple entities including the processing system. The computer-readable medium may be embodied in a computer-program product. By way of example, a computer-program product may include a computer-readable medium in packaging materials. Those skilled in the art will recognize how best to implement the described functionality presented throughout this disclosure depending on the particular application and the overall design constraints imposed on the overall system.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover: a; b; c; a and b; a and c; b and c; and a, b and c. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112 (f), unless the element is expressly recited using the phrase “means for” or, in the case of a method claim, the element is recited using the phrase “step for.”

What is claimed is:

1. A method of determining whether an encoded multi-part message in a channel is intended for a user equipment (UE), the method comprising:
receiving a codeword, wherein the codeword is a component of the encoded multi-part message;
demasking the received codeword based on an assigned identifier assigned to the UE to provide a data sequence;
demasking the received codeword based on re-encoding the data sequence to provide a detected identifier; and
comparing the detected identifier to the assigned identifier, wherein the UE is determined to be the intended recipient of the encoded multi-part message when the detected identifier is equal to the assigned identifier.

2. The method of claim 1, wherein the communications device is determined to not be the intended recipient of the encoded multi-part message when the detected identifier is not equal to the assigned identifier.

3. The method of claim 1, wherein the transmission of the multi-part message is determined to be discontinuous when the detected identifier is not equal to the assigned identifier.

4. The method of claim 1, wherein demasking the received codeword based on the assigned identifier further comprises:
deriving a mask from the assigned identifier;
demasking the received codeword using the mask derived from the assigned identifier to provide a demasked codeword; and
decoding the demasked codeword to produce the data sequence.

5. The method of claim 1, wherein demasking the received codeword further comprises:
re-encoding the data sequence;
demasking the received codeword using the re-encoded data sequence to provide a detected mask; and
decoding the detected mask to provide the detected identifier.

6. The method of claim 1, wherein the encoded multi-part message comprises a high-speed shared control channel (HS-SCCH) message having a part 1 and a part 2, and the received codeword comprises the part 1 of the HS-SCCH message.

7. The method of claim 6, wherein the communications device only receives the part 2 of the HS-SCCH message when the communications device is determined to be the intended recipient of the HS-SCCH message.

8. An apparatus for determining whether an encoded multi-part message in a channel is intended for a user equipment, the method comprising:
at least one processor;
a transceiver configured to receive at least the encoded multi-part message;
a memory; and
a bus coupled to the at least one processor, transceiver, and memory, wherein the at least one processor and memory are configured to:
receive a codeword, wherein the codeword is a component of the encoded multi-part message;
demask the received codeword based on an assigned identifier assigned to the communications device to provide a data sequence;
demasking the received codeword based on re-encoding the data sequence to provide a detected identifier; and
compare the detected identifier to the assigned identifier, wherein the communication device is determined to be the intended recipient of the encoded multi-part message when the detected identifier is equal to the assigned identifier.

9. The apparatus of claim 8, wherein the user equipment is determined to not be the intended recipient of the encoded multi-part message when the detected identifier is not equal to the assigned identifier.

10. The apparatus of claim 8, wherein the transmission of the multi-part message is determined to be discontinuous when the detected identifier is not equal to the assigned identifier.

11. The apparatus of claim 8, wherein the at least one processor, when configured to demask the received codeword based on the assigned identifier, is further configured to:
derive a mask from the assigned identifier;
demask the received codeword using the mask derived from the assigned identifier to provide a demasked codeword; and
decode the demasked codeword to produce the data sequence.

12. The apparatus of claim 8, wherein the at least one processor, when configured to demask the received codeword, is further configured to:
re-encode the data sequence;
demask the received codeword using the re-encoded data sequence to produce a detected mask; and
decode the detected mask to provide the detected identifier.

13. The apparatus of claim 8, wherein the encoded multi-part message comprises a high-speed shared control channel (HS-SCCH) message having a part 1 and a part 2, and the received codeword comprises the part 1 of the HS-SCCH message.

14. The apparatus of claim 13, wherein the communications device only receives the part 2 of the HS-SCCH message when the communications device is determined to be the intended recipient of the HS-SCCH message.

15. A method of decoding an encoded multi-part message in a channel, the method comprising:
choosing an initial value for an iterative identifier;
iterating, until the value of the iterative identifier converges to within a predetermined threshold, including:
deriving a mask from the iterative identifier,
demasking a received codeword based on the derived mask to provide an iterative data sequence, wherein the received codeword is a component of the encoded multi-part message, and
demasking the received codeword based on the iterative data sequence to provide an updated value for the iterative identifier, wherein the iterative data sequence is re-encoded;
re-masking the iterative data sequence using the derived mask based on the iterative identifier and the re-encoded iterative data sequence at a point of convergence; and
computing a correlation value between the re-masked iterative data sequence and the received codeword.

16. The method of claim 15, wherein the identifier comprises a high-speed downlink shared channel (HS-DSCH) radio network temporary identifier (H-RNTI).

17. The method of claim 15, wherein the iterating ends after a preset maximal number of iterations is performed.

18. The method of claim 15, wherein the iterating ends after a predetermined period of time.

19. The method of claim 15, further comprising:
choosing a mask that produces the re-masked iterative data sequence associated with the highest correlation value relative to the received codeword.

20. The method of claim 19, further comprising:
de-masking the encoded multi-part message using the chosen mask.

21. An apparatus for decoding an encoded multi-part message in a channel, the apparatus comprising:
at least one processor;
a transceiver configured to receive at least the encoded multi-part message;
a memory; and
a bus coupled to the at least one processor, transceiver, and memory, wherein the at least one processor and memory are configured to:
choose an initial value for an iterative identifier;
iterate, until the value of the iterative identifier converges to within a predetermined threshold, including:
deriving a mask from the iterative identifier,
demasking a received codeword message based on the derived mask to provide an iterative data sequence, wherein the receive codeword is a component of the encoded multi-part message, and
demasking the received codeword and based on iterative data sequence to provide an updated value for the iterative identifier, wherein the initial or iterative data sequence is re-encoded;
re-masking the iterative data sequence using the derived mask based on the iterative identifier and the re-encoded iterative data sequence at a point of convergence; and
compute a correlation value between the re-masked iterative data sequence and the received codeword.

22. The apparatus of claim 21, wherein the identifier comprises a high-speed downlink shared channel (HS-DSCH) radio network temporary identifier (H-RNTI).

23. The apparatus of claim 21, wherein the at least one processor, when configured to iterate, ends after a preset maximal number of iterations is performed.

24. The apparatus of claim 21, wherein the at least one processor, when configured to iterate, ends after a predetermined period of time.

25. The apparatus of claim 21, wherein the at least one processor is further configured to:
choose a mask that produces the re-masked iterative data sequence associated with the highest correlation value relative to the received codeword.

26. The apparatus of claim 23, wherein the at least one processor is further configured to:
demask the encoded multi-part message using the chosen mask.
